(19) United States
(12) Patent Application Publication
(10) Pub. No.: US 2025/0362268 A1
(43) Pub. Date: Nov. 27, 2025

(54) MATERIAL ANALYSIS APPARATUS AND MATERIAL ANALYSIS METHOD

(71) Applicant: ELECTRONICS AND TELECOMMUNICATIONS RESEARCH INSTITUTE, Daejeon (KR)

(72) Inventors: Hyo Bong HONG, Daejeon (KR); JAE-CHAN JEONG, Daejeon (KR)

(21) Appl. No.: 19/212,113

(22) Filed: May 19, 2025

(30) Foreign Application Priority Data
May 22, 2024 (KR) 10-2024-0066749
Mar. 25, 2025 (KR) 10-2025-0038127

(51) Int. Cl. G01N 27/74; G01R 33/12

(52) U.S. Cl. CPC G01N 27/74; G01R 33/1276

(57) ABSTRACT

Provided is a material analysis method including applying a magnetic field to each of a first measurement target material and a second measurement target material, detecting each of a first magnetization signal of the first measurement target material and a second magnetization signal of the second measurement target material, extracting a first harmonic pattern from the first magnetization signal and extracting a second harmonic pattern from the second magnetization signal, and analyzing a difference between the first harmonic pattern and the second harmonic pattern to analyze a difference between the first measurement target material and the second measurement target material.

### CROSS-REFERENCE TO RELATED APPLICATIONS

This U.S. non-provisional patent application claims priority under 35U.S.C. § 119 of Korean Patent Application Nos. 10-2024-0066749, filed on May 22, 2024, and 10-2025-0038127, filed on Mar. 25, 2025, the entire contents of which are hereby incorporated by reference.

### BACKGROUND

The present disclosure herein relates to a material analysis apparatus and a material analysis method using the same. More specifically, the present disclosure herein relates to an apparatus and method for separating and analyzing super-paramagnetic particles by analyzing patterns of harmonic signals of the super-paramagnetic particles generated in AC and DC magnetic fields.

Nano-sized particles having super-paramagnetic properties are being used in various industrial fields. In particular, iron oxide (e.g., black iron oxide and red iron oxide) is used for medical and biosensor applications and also utilized as nano-sized particles having the super-paramagnetic properties. These nanoparticles may change in magnetic properties depending on temperature, size, and shape thereof, which is known as magnetic phase transformation.

The magnetic phase transformation caused by temperature, among the factors that cause the magnetic phase transformation of nanoparticles, occurs only at temperatures above several hundred degrees Celsius or near absolute temperature, and thus does not occur in living organisms or in general environments. However, regardless of the temperature mentioned above, when the size of the nanoparticles falls below a certain level (for example, below about 100 nm), the magnetic properties of the nanoparticles change significantly.

For example, the black iron oxide has diamagnetic or strong paramagnetic properties when existing as minerals. However, when the size of black iron oxide is about 100 nm, the phase transformation to the super-paramagnetic state may occur. For example, in the red iron oxide, the same phase transformation behavior as the black iron oxide described above may be observed.

Therefore, in order to analyze the synthesis of nanoparticles or the generation and extinction of biogenic particles for commercial purposes, there is a need for a technology capable of identifying changes in the properties of nanoparticles as described above. The related art for analyzing the properties of nanoparticles as described above includes XPS, TEM-EELS, SEM-EDAX, MPMS, and MPS. However, the related art has limitations in analyzing the magnetic properties of nanoparticles that may appear in synthesis and biological reactions.

### SUMMARY

The present disclosure provides a theoretical principle, method, and analysis apparatus for separating/analyzing nanoparticles by identifying the differences in the magnetic moments between nanoparticles, which most clearly represent the magnetic properties of nanoparticles.

The objects of the present disclosure are not limited to the aforementioned object, but other objects not described herein will be clearly understood by those skilled in the art from the following description.

An embodiment of the inventive concept provides a material analysis method including applying a magnetic field to each of a first measurement target material and a second measurement target material, detecting each of a first magnetization signal of the first measurement target material and a second magnetization signal of the second measurement target material, extracting a first harmonic pattern from the first magnetization signal and extracting a second harmonic pattern from the second magnetization signal, and analyzing a difference between the first harmonic pattern and the second harmonic pattern to analyze a difference between the first measurement target material and the second measurement target material.

In an embodiment of the inventive concept, a material analysis method includes applying, by a generation unit, a magnetic field to each of a first measurement target material and a second measurement target material, detecting, by a detection unit, each of a first magnetization signal of the first measurement target material and a second magnetization signal of the second measurement target material, extracting, by an analysis unit, a first harmonic pattern from the first magnetization signal and extracting, by the analysis unit, a second harmonic pattern from the second magnetization signal, and analyzing, by the analysis unit, a difference between the first harmonic pattern and the second harmonic pattern to analyze a difference between the first measurement target material and the second measurement target material, wherein, when detecting each of the first magnetization signal and the second magnetization signal, a temperature of each of the first and second measurement target materials is adjusted by a sample temperature adjustment device.

In an embodiment of the inventive concept, a material analysis apparatus includes a generation unit configured to apply a magnetic field to each of a first measurement target material and a second measurement target material, a detection unit configured to detect each of a first magnetization signal of the first measurement target material and a second magnetization signal of the second measurement target material, an analysis unit configured to extract a first harmonic pattern from the first magnetization signal and extract a second harmonic pattern from the second magnetization signal, and a sample temperature adjustment device configured to control each of a temperature of the first measurement target material and a temperature of the second measurement target material, inside the detection unit, wherein the analysis unit analyzes a difference between the first harmonic pattern and the second harmonic pattern to analyze a difference between the first measurement target material and the second measurement target material.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept.

In the drawings:

FIG. 1 is a block diagram showing a material analysis apparatus;

FIG. 2 is a perspective view showing a detection unit of FIG. 1;

FIG. 3 is a cross-sectional view showing a first coil and a second coil of FIG. 2;

FIG. 4 is a flowchart showing a method for analyzing a material; and

FIG. 5 is a graph showing magnetic moments of experimental examples according to frequencies.

### DETAILED DESCRIPTION

Hereinafter, embodiments of the inventive concept will be described in detail with reference to the accompanying drawings. Advantages and features of the present disclosure, and implementation methods thereof will be clarified through following embodiments described in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the concept of the present disclosure to those skilled in the art. Further, the present disclosure is only defined by scopes of claims. Like reference numerals refer to like elements throughout.

The terms used herein are used only for explaining embodiments while not limiting the present disclosure. In this specification, the singular forms include the plural forms as well, unless the context clearly indicates otherwise. The meaning of ‘comprises’ and/or ‘comprising’ used in the specification does not exclude the presence or addition of one or more components, steps, operations, and/or elements other than the mentioned components, steps, operations, and/or devices. Since preferred embodiments are provided below, the order of the reference numerals given in the description is not limited thereto.

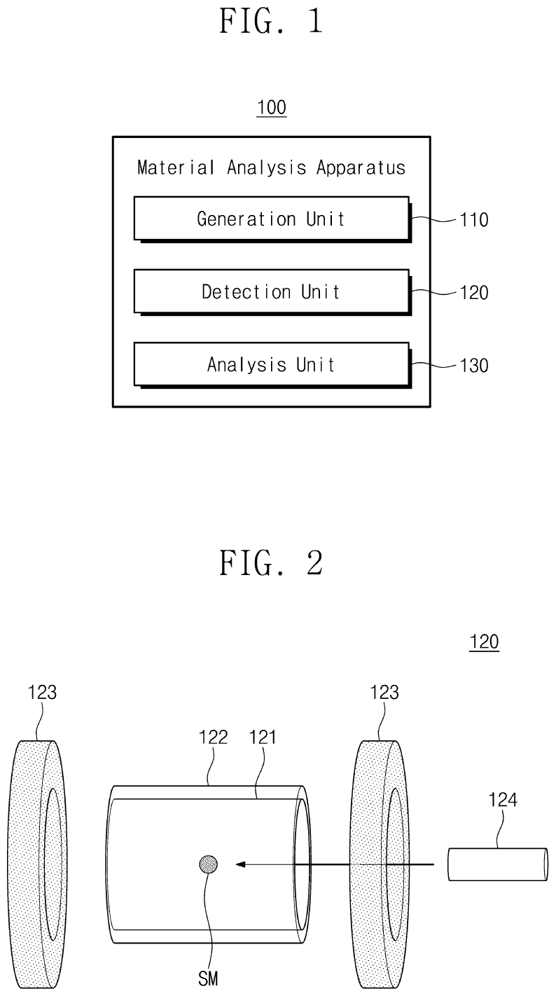

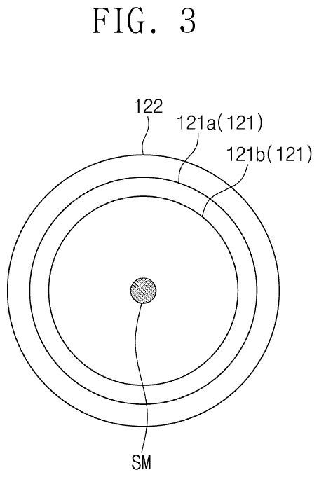

FIG. 1 is a block diagram showing a material analysis apparatus 100. FIG. 2 is a perspective view showing a detection unit 120 of FIG. 1. FIG. 3 is a cross-sectional view showing a first coil 121 and a second coil 122 of FIG. 2.

Referring to FIG. 1, the material analysis apparatus 100 may include a generation unit 110, the detection unit 120, and an analysis unit 130. The generation unit 110 may generate a magnetic field that is applied to a material to be measured (hereinafter, referred to as a measurement target material). The generation unit 110 may include an alternating current (AC) signal source (not shown) and a first amplifier (not shown). The AC signal source may provide a source signal that is required to create an AC magnetic field. The first amplifier may amplify the signal applied from the AC signal source. The generation unit 110 may be provided in spaces at room temperature and atmospheric pressure.

The detection unit 120 may detect a magnetization signal generated from the measurement target material as the magnetic field created by the generation unit 110 is applied to the measurement target material. The specific configuration of the detection unit 120 is described with reference to FIGS. 2 and 3. The detection unit 120 may be provided in spaces at room temperature and atmospheric pressure.

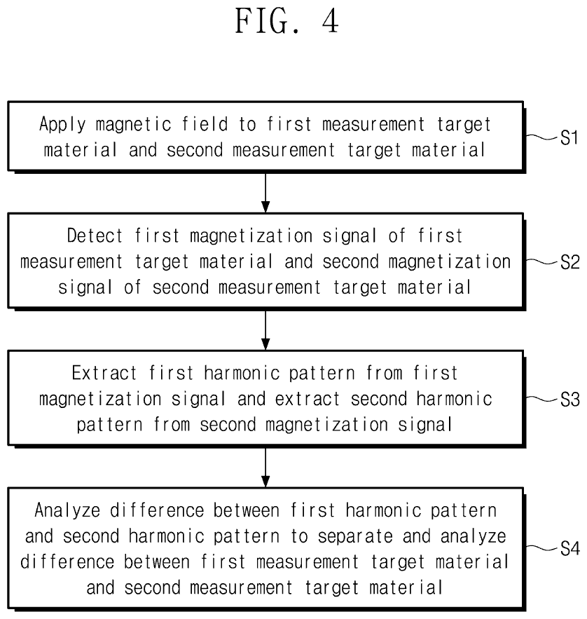

The analysis unit 130 may analyze the measurement target material on the basis of a harmonic pattern from the magnetization signal detected by the detection unit 120. A method for analyzing the measurement target material on the basis of the harmonic pattern is described with reference to FIG. 4.

The analysis unit 130 may include a second amplifier (not shown), a filter (not shown), a third amplifier (not shown), a spectrum analyzer (not shown), and a personal computer (PC) (not shown). The second amplifier may amplify the signal generated by the detection unit 120. The filter may filter only a specific frequency range by targeting frequencies to be measured in signals amplified by the second amplifier. The third amplifier may amplify the signals that have been weakened while passing through the filter. The spectrum analyzer may extract the harmonic pattern from the magnetization signal of the measurement target material. In particular, the spectrum analyzer may extract harmonic patterns from magnetization signals of a plurality of measurement target materials to separate and analyze the measurement target materials. The PC may perform all system control of the material analysis apparatus 100.

Referring to FIGS. 1 to 3, the detection unit 120 may include first to third coils 121, 122, and 123 and a sample temperature adjustment device 124. The first coil 121 may include an excitation coil 121a and a detection coil 121b. For example, the excitation coil 121a may surround the detection coil 121b. For example, the generation unit 110 may input an alternating current into the excitation coil 121a, and the excitation coil 121a may create a magnetic field. The magnetic field may be applied to a measurement target material SM. Accordingly, the detection coil 121b may detect the magnetization signal generated from the measurement target material SM.

The second coil 122 may surround the first coil 121. A pair of third coils 123 may be spaced apart from each other with the first and second coils 121 and 122 therebetween. The pair of third coils 123 may be respectively arranged at both ends of each of the first and second coils 121 and 122. For example, the third coils 123 may include a Helmholtz coil.

A direct current (DC) may be applied to the second coil 122 and the third coils 123. Accordingly, the second coil 122 and the third coils 123 may create a DC magnetic field. The internal magnetic field may become flat due to the magnetic field generated by the second coil 122 and the third coils 123.

The sample temperature adjustment device 124 may adjust the temperature of the measurement target material SM. Since the temperature of the measurement target material SM is directly related to the signal of magnetization of the measurement target material SM (see equation described below), the sample temperature adjustment device 124 may adjust the temperature of the measurement target material SM to accurately measure the signal of magnetization of the measurement target material SM. For example, the sample temperature adjustment device 124 may include a chiller.

The detection unit 120 may further include a coil temperature adjustment device (not shown) that adjusts the temperature of the first to third coils 121, 122, and 123. For example, the coil temperature adjustment device may include a chiller. Since the temperature of the first to third coils 121, 122, and 123 is directly related to the amount of current consumed to drive the first to third coils 121, 122, and 123, the coil temperature adjustment device may adjust the temperature of the first to third coils 121, 122, and 123 so that constant current may be supplied to the first to third coils 121, 122, and 123.

FIG. 4 is a flowchart showing a method for analyzing a material.

First, prior to describing the method for measuring the measurement target material in detail, the theoretical background underlying the measurement method is described.

For example, the measurement target material may include nanoparticles. For example, the measurement target material may include super-paramagnetic particles having super-paramagnetic properties. For example, the measurement target material may include super-paramagnetic iron oxide (SPIO). The measurement target material having the super-paramagnetic properties may exhibit an intense magnetic response only when a magnetic field is present, and once the magnetic field is removed, no remnant magnetization may remain. This is because when an external magnetic field is applied to the measurement target material, magnetic dipoles are aligned and magnetized, but when the magnetic field is removed, the magnetic dipoles return to a random state.

The Langevin function may be used to describe the properties of the measurement target material having the super-paramagnetic properties. The Langevin function represents the average magnetization of super-paramagnetic particles according to the intensity of the magnetic field and temperature. The Langevin function is a mathematical model that represents magnetization (M) of the super-paramagnetic measurement target material and may be used to describe the response of the measurement target material to an external magnetic field.

First, the Langevin function is as follows.

$$L ( x ) = coth ( x ) - \frac{1}{x}$$

Here, x is as follows.

$$x = \frac{{μ}_{0} {M}_{n} H ( t )}{{κ}_{h} T}$$

Here, μ₀ is the magnetic permeability, Mₙ is the magnetic moment of a single particle, H(t) is the magnetic field over time, K_{b} is the Boltzmann constant, and T is the absolute temperature.

The equation for the magnetization (M) of the measurement target material obtained by using the Langevin function is as follows.

$$M = {M}_{S} L ( x )$$

The Langevin function may be used to obtain the magnetization of the measurement target materials as described above and to compare the magnetization. Here, M_{S} represents the saturation magnetization of the measurement target material. When measuring the magnetization of the measurement target materials, among variables of x in the Langevin function, the magnetic permeability, the magnetic field over time, the Boltzmann constant, and the absolute temperature are the constant conditions. Therefore, under the condition that the above conditions are constant, factors that may cause differences in the magnetization of the measurement target materials may be M_{S} and Mₙ.

To satisfy the condition that the above conditions are constant, especially when temperature (T) of the measurement target materials varies, the difference in M_{S} and Mₙ of the measurement target materials may not be properly analyzed. Therefore, as described above, the temperature of the measurement target materials may be adjusted by using the sample temperature adjustment device 124 described with reference to FIG. 2. As a result, the reliability of a material measurement method described below may be improved.

For example, when assuming that a first measurement target material and a second measurement target material are measured under the same experimental conditions (i.e., the magnetic permeability, the magnetic field over time, the Boltzmann constant, the absolute temperature, or the like are constant), the function of the magnetization of the first measurement target material is expressed as Equation (1), and the function of the magnetization of the second measurement target material is expressed as Equation (2).

$$M ( {x}_{1} ) = {M}_{S 1} L ( {x}_{1} ) = {M}_{S 1} ( coth ( {x}_{1} ) - \frac{1}{{x}_{1}} ) \qquad ( 1 )$$

$$M ( {x}_{2} ) = {M}_{S 2} L ( {x}_{2} ) = {M}_{S 2} ( coth ( {x}_{2} ) - \frac{1}{{x}_{2}} ) \qquad ( 2 )$$

As described above, when M_{S} and Mₙ are factors related to the properties of magnetization of the measurement target material, two possible cases may be considered to see whether each of the difference in M_{S} between the first measurement target material and the second measurement target material and the difference in Mₙ between the first measurement target material and the second measurement target material may produce the difference between the slope of the magnetization of the first measurement target material and the slope of the magnetization of the second measurement target material.

$$Case 1 : {M}_{S 1} \neq {M}_{S 2} , {M}_{n 1} = {M}_{n 2} \\ Case 2 : {M}_{S 1} = {M}_{S 2} , {M}_{n 1} \neq {M}_{n 2}$$

In Case 1, M_{S} of the first measurement target material is different from M_{S} of the second measurement target material, and Mₙ of the first measurement target material is the same as Mₙ of the second measurement target material. In Case 2, M_{S} of the first measurement target material is the same as M_{S} of the second measurement target material, and Mₙ of the first measurement target material is different from Mₙ of the second measurement target material. In each of Case 1 and Case 2 above, when arbitrary values of M_{S} and Mₙ are input into each of Equation (1) and Equation (2) and then the differentiation is performed, the following results are obtained.

First, in Case 1, when M_{S1} is 2, M_{S2} is 1.5, Mₙ₁ is 1, and Mₙ₂ is 1, Equation (3) may be obtained by differentiating Equation (1), and Equation (4) may be obtained by differentiating Equation (2).

$${M}^{′} ( {x}_{1} ) = 2 ( \frac{1}{{x}_{1}^{2}} - {coth ( {x}_{1} )}^{2} + 1 ) \qquad ( 3 )$$

$${M}^{′} ( {x}_{2} ) = 1.5 ( \frac{1}{{x}_{2}^{2}} - {coth ( {x}_{2} )}^{2} + 1 ) \qquad ( 4 )$$

When M_{S} of the first measurement target material is different from M_{S} of the second measurement target material, and Mₙ of the first measurement target material is the same as Mₙ of the second measurement target material, only the coefficients of the derivatives of Equation (3) and Equation (4) are different from each other. Therefore, when a different multiple is applied to either the function of the magnetization of the first measurement target material or the function of the magnetization of the second measurement target material, these two functions may overlap with each other.

Next, in Case 2, when M_{S1} and M_{S2} are 1, Mₙ₁ is 1, and Mₙ₂ is 2, Equation (5) may be obtained by differentiating Equation (1), and Equation (6) may be obtained by differentiating Equation (2).

$${M}^{′} ( {x}_{1} ) = \frac{1}{{x}_{1}^{2}} - {coth ( {x}_{1} )}^{2} + 1 \qquad ( 5 )$$

$${M}^{′} ( {x}_{2} ) = \frac{1}{2 {x}_{2}^{2}} - 2 {coth ( 2 {x}_{2} )}^{2} + 2 \qquad ( 6 )$$

When M_{S} of the first measurement target material is the same as M_{S} of the second measurement target material, and Mₙ of the first measurement target material is different from Mₙ of the second measurement target material, the coefficients of all terms in the derivatives of Equation (5) and Equation (6) are different from each other. That is, even when a different multiple is applied to either the function of the magnetization of the first measurement target material or the function of the magnetization of the second measurement target material, these two functions may not overlap with each other.

Furthermore, in addition to the first-order derivative in Case 1, the second- and third-order derivatives are calculated as follows. First, the first-order derivative in Case 1 is differentiated. That is, Equation (7) is obtained by differentiating Equation (3), and Equation (8) is obtained by differentiating Equation (4).

$${M}^{″} ( {x}_{1} ) = - 2 ( \frac{2}{tanh {x}_{1}} - \frac{2}{{tanh}^{3} {x}_{1}} + \frac{2}{{x}_{1}^{3}} ) \qquad ( 7 )$$

$${M}^{″} ( {x}_{2} ) = - 1.5 ( \frac{2}{tanh {x}_{2}} - \frac{2}{{tanh}^{3} {x}_{2}} + \frac{2}{{x}_{2}^{3}} ) \qquad ( 8 )$$

When M_{S} of the first measurement target material is different from M_{S} of the second measurement target material, and Mₙ of the first measurement target material is the same as Mₙ of the second measurement target material, only the coefficients of the second-order derivatives of Equation (7) and Equation (8) are different from each other.

Furthermore, the second-order derivative in Case 1 is differentiated. That is, Equation (9) is obtained by differentiating Equation (7), and Equation (10) is obtained by differentiating Equation (8).

$${M}^{′′′} ( {x}_{1} ) = - 2 ( \frac{4}{{sinh}^{2} {x}_{1}} + \frac{6}{{sinh}^{4} {x}_{1}} - \frac{6}{{x}_{1}^{4}} ) \qquad ( 9 )$$

$${M}^{′′′} ( {x}_{2} ) = - 1.5 ( \frac{4}{{sinh}^{2} {x}_{2}} + \frac{6}{{sinh}^{4} {x}_{2}} - \frac{6}{{x}_{2}^{4}} ) \qquad ( 10 )$$

In summary, in Case 1, the nth-order derivative of the magnetization of the first measurement target material and the nth-order derivative of the magnetization of the second measurement target material may be different from each other only with respect to the coefficients. Here, n is an integer greater than 0. Therefore, in Case 1, the function of the magnetization of the first measurement target material and the function of the magnetization of the second measurement target material may be different from each other only with respect to the slope.

Similarly, in addition to the first-order derivative in Case 2, the second- and third-order derivatives are calculated as follows. First, the first-order derivative in Case 2 is differentiated. That is, Equation (11) is obtained by differentiating Equation (5), and Equation (12) is obtained by differentiating Equation (6).

$${M}^{″} ( {x}_{1} ) = - 2 ( \frac{1}{tanh {x}_{1}} - \frac{1}{{tanh}^{3} {x}_{1}} + \frac{1}{{x}_{1}^{3}} ) \qquad ( 11 )$$

$${M}^{″} ( {x}_{2} ) = - 8 ( \frac{1}{tanh 2 {x}_{2}} - \frac{1}{{tanh}^{3} 2 {x}_{2}} + \frac{1}{8 {x}_{2}^{3}} ) \qquad ( 12 )$$

Furthermore, the second-order derivative in Case 2 is differentiated. That is, Equation (13) is obtained by differentiating Equation (11), and Equation (13) is obtained by differentiating Equation (12).

$${M}^{′′′} ( {x}_{1} ) = - ( \frac{4}{{sinh}^{2} {x}_{1}} + \frac{6}{{sinh}^{4} {x}_{1}} - \frac{6}{{x}_{1}^{4}} ) \qquad ( 13 )$$

$${M}^{′′′} ( {x}_{2} ) = - 8 ( \frac{4}{{sinh}^{2} {x}_{2}} + \frac{6}{{sinh}^{4} {x}_{2}} - \frac{3}{8 {x}_{2}^{4}} ) \qquad ( 14 )$$

In summary, in Case 1, even when a multiple is applied to either the nth-order derivative of the magnetization of the first measurement target material or the nth-order derivative of the magnetization of the second measurement target material, these two nth-order derivatives may not overlap with each other.

In summary, L(ₓ_{₁}) is the Langevin equation of the first measurement target material, and L(ₓ_{₂}) is the Langevin equation of the second measurement target material. When the first measurement target material and the second measurement target material are different from each other only with respect to M_{S}, the following relation is established.

$$L ( {x}_{1} ) = {n}_{1} L ( {x}_{2} ) , {L}^{′} ( {x}_{1} ) = {n}_{2} {L}^{′} ( {x}_{2} ) , {L}^{″} ( {x}_{1} ) = {n}_{3} {L}^{″} ( {x}_{2} ) , {L}^{′′′} ( {x}_{1} ) = {n}_{4} {L}^{′′′} ( {x}_{2} )$$

On the other hand, when the first measurement target material and the second measurement target material are different from each other only with respect to Mₙ, the following relation is established.

$$L ( {x}_{1} ) \neq {n}_{1} L ( {x}_{2} ) , {L}^{′} ( {x}_{1} ) \neq {n}_{2} {L}^{′} ( {x}_{2} ) , {L}^{″} ( {x}_{1} ) \neq {n}_{3} {L}^{″} ( {x}_{2} ) , {L}^{′′′} ( {x}_{1} ) \neq {n}_{4} {L}^{′′′} ( {x}_{2} )$$

As described above, when the first measurement target material and the second measurement target material are different from each other only with respect to M_{S}, the derivative of the magnetization of the first measurement target material and the derivative of the magnetization of the second measurement target material may be different from each other only with respect to the coefficients, and the derivatives themselves may be equal to each other. As a result, different multiples may be applied to the function of the magnetization of the first measurement target material and the function of the magnetization of the second measurement target material, and thus, these two functions may overlap with each other. For example, even when the function of the magnetization of the first measurement target material and the function of the magnetization of the second measurement target material are different from each other, these two functions may become equal to each other by adjusting the amount of either the first measurement target material or the second measurement target material. Therefore, when the first measurement target material and the second measurement target material are different from each other only with respect to M_{S}, it may not be possible to perform separation and analysis on the first measurement target material and the second measurement target material by using the function of magnetization.

On the other hand, when the first measurement target material and the second measurement target material are different from each other only with respect to Mₙ as described above, the derivative of the magnetization of the first measurement target material and the derivative of the magnetization of the second measurement target material may be different from each other with respect to the coefficients of the terms in the equations. Accordingly, even when different multiples are applied to the function of the magnetization of the first measurement target material and the function of the magnetization of the second measurement target material, these two functions may not overlap with each other. That is, even when the amount of either the first measurement target material or the second measurement target material is adjusted, the function of the magnetization of the first measurement target material and the function of the magnetization of the second measurement target material may not overlap with each other. Therefore, when the first measurement target material and the second measurement target material are different from each other only with respect to Mₙ, it may be possible to perform separation and analysis on the first measurement target material and the second measurement target material by using the function of magnetization.

Based on the theoretical background described above, a method for separating and analyzing specific measurement target materials is described in detail below.

Referring to FIG. 4, a material measurement method according to the inventive concept may include a first step S1 of applying a magnetic field to a first measurement target material and a second measurement target material, a second step S2 of detecting a first magnetization signal of the first measurement target material and a second magnetization signal of the second measurement target material, which have been generated by applying the magnetic field to the first and second measurement target materials, a third step S3 of extracting a first harmonic pattern from the first magnetization signal and a second harmonic pattern from the second magnetization signal, and a fourth step S4 of analyzing the difference between the first harmonic pattern and the second harmonic pattern to separate and analyze the first measurement target material and the second measurement target material.

In first step S1, the first measurement target material and the second measurement target material each include the measurement target material SM described with reference to FIG. 2. For example, the first measurement target material and the second measurement target material may include super-paramagnetic materials. For example, the first measurement target material and the second measurement target material may include the same material and have different sizes. For example, the first measurement target material and the second measurement target material may each have a size of about 0.1 nm to about 100 nm.

Also, the magnetic field may be generated by the generation unit 110 and the excitation coil 121a of the detection unit 120 as described with reference to FIGS. 1 to 3. In second step S2, the detection coil 121b described with reference to FIG. 3 may detect the magnetization signal. In third step S3, the analysis unit 130 described with reference to FIG. 1 may extract the harmonic pattern from the magnetization signal. In fourth step S4, the analysis unit 130 described with reference to FIG. 1 may analyze the difference between the first harmonic pattern and the second harmonic pattern to analyze the difference between the first measurement target material and the second measurement target material.

For example, the extracting of the first harmonic pattern of the first measurement target material in third step S3 may include extracting first harmonic peaks by expanding the Langevin function of the first magnetization signal into a Taylor series. The Langevin function of the first magnetization signal of the first measurement target material may be obtained from Equation (1) described above. Equation (15) may be obtained by expanding the Langevin function of the first magnetization signal into a Taylor series. The first harmonic peaks may be obtained by using Equation (15) below.

$${\sum }_{n = 0}^{∞} \frac{L ( {x}_{1} ) ( a )}{n !} = L ( a ) + {L}^{′} ( a ) ( {x}_{1} - a ) + \frac{{L}^{″} ( a )}{2 !} {( {x}_{1} - a )}^{2} + \frac{{L}^{′′′} ( a )}{3 !} {( {x}_{1} - a )}^{3} … \qquad ( 15 )$$

For example, the extracting of the second harmonic pattern of the second measurement target material in third step S3 may include extracting second harmonic peaks by expanding the Langevin function of the second magnetization signal into a Taylor series. The Langevin function of the second magnetization signal of the second measurement target material may be obtained from Equation (2) described above. Equation (16) may be obtained by expanding the Langevin function of the second magnetization signal into a Taylor series. The second harmonic peaks may be obtained by using Equation (16) below.

$${\sum }_{n = 0}^{∞} \frac{L ( {x}_{2} ) ( a )}{n !} = L ( a ) + {L}^{′} ( a ) ( {x}_{2} - a ) + \frac{{L}^{″} ( a )}{2 !} {( {x}_{2} - a )}^{2} + \frac{{L}^{′′′} ( a )}{3 !} {( {x}_{2} - a )}^{3} … \qquad ( 16 )$$

As described above, when M_{S} of the first measurement target material is different from M_{S} of the second measurement target material, the first harmonic patterns of Equation (15) and the second harmonic patterns of Equation (16) are shown in Equation (17) below.

$${L}^{( n )} ( {x}_{1} ) = {n}_{n} {L}^{( n )} ( {x}_{2} ) \qquad ( 17 )$$

As described above, when Mₙ of the first measurement target material is different from Mₙ of the second measurement target material, the first harmonic patterns of Equation (15) and the second harmonic patterns of Equation (16) are shown in Equation (18) below.

$${L}^{( n )} ( {x}_{1} ) \neq {n}_{n} {L}^{( n )} ( {x}_{2} ) \qquad ( 18 )$$

For example, in fourth step S4, the difference in Equation (18) (i.e., the difference between the first harmonic pattern and the second harmonic pattern) may be analyzed, and thus, the difference between the first measurement target material and the second measurement target material may be analyzed.

For example, in fourth step S4, the difference in Equation (18) (i.e., the difference between the first harmonic pattern and the second harmonic pattern) may be analyzed, and thus, the difference between the magnetic moment of the first measurement target material and the magnetic moment of the second measurement target material may be analyzed.

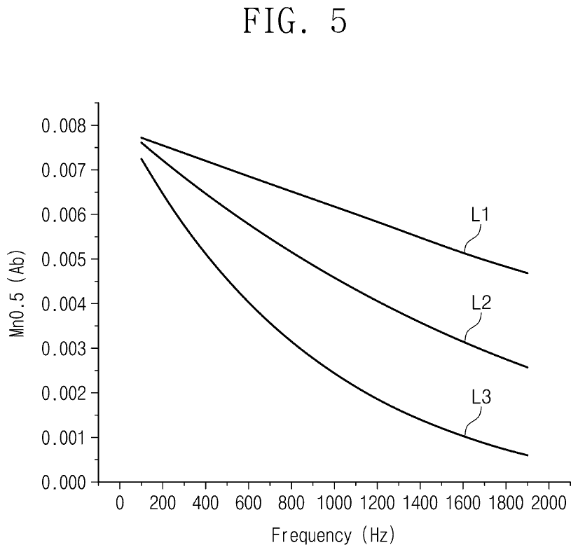

FIG. 5 is a graph showing magnetic moments of experimental examples according to frequencies.

Referring to FIG. 5, the first to third experimental examples are provided. The first to third experimental examples include iron oxide particles. The particle size of the first experimental example is about 70 nm, the particle size of the second experimental example is about 50 nm, and the particle size of the third experimental example is about 130 nm. The dosage of the first to third experimental examples is about 25 mg/mL when the solution is about 300 μL.

In the graph, the X-axis represents the frequency and the Y-axis represents the magnetic moment. For example, except for the values of the magnetic moments (Mₙ) of the first to third experimental examples, the experimental conditions (e.g., the magnetic permeability, the magnetic field over time, the Boltzmann constant, and the absolute temperature) may be constant as described above.

The first to third experimental examples may be measured by the material measurement method described with reference to FIG. 4. Accordingly, the intensities of harmonic peaks may be generated and measured. All signals of the intensities of harmonic peaks may be normalized between about 0 and about 1 by using calculation software, such as Origin. By using the normalized data, the graph described with reference to FIG. 5 may be fitted.

A first curve L1 represents a trend line of the first experiment. A second curve L2 represents a trend line of the second experiment. A third curve L3 represents a trend line of the third experiment. The first to third lines L1, L2, and L3 may represent trend lines obtained by using the material measurement method described with reference to FIG. 4. For example, the first curve L1 may represent a graph in which the magnetic moments are fitted according to the frequencies by analyzing the first harmonic patterns of the first experimental example. The second curve L2 may represent a graph in which the magnetic moments are fitted according to the frequencies by analyzing the second harmonic patterns of the second experimental example. The third curve L3 may represent a graph in which the magnetic moments are fitted according to the frequencies by analyzing the third harmonic patterns of the third experimental example.

For example, the first to third experimental examples have the same material (e.g., the iron oxide nanoparticles), but have different sizes. Accordingly, the magnetic moments of the first to third experimental examples may be different from each other. As a result, the first to third harmonic patterns may be different from each other, and thus, the shapes of the first to third curves L1, L2, and L3 may be different from each other. In other words, even when different multiples are applied to the functions of magnetization of the first to third experimental examples, these functions may not overlap with each other. That is, as illustrated in the graph of FIG. 5, the first to third experimental examples may be separated and analyzed by using the material measurement method described with reference to FIG. 4.

According to the inventive concept, provided are the theoretical principles, the separation analysis method for nanoparticles using the same, and the separation analysis device, capable of identifying the differences between magnetic moments that most clearly represent the magnetic properties of nanoparticles. Accordingly, it may be easier to perform the separation and analysis on the magnetic properties of nanoparticles.

Although the embodiments of the present invention have been described, it is understood that the present invention should not be limited to these embodiments but various changes and modifications can be made by one ordinary skilled in the art within the spirit and scope of the present invention as hereinafter claimed.

What is claimed is:

1. A material analysis method comprising:
applying a magnetic field to each of a first measurement target material and a second measurement target material;
detecting each of a first magnetization signal of the first measurement target material and a second magnetization signal of the second measurement target material;
extracting a first harmonic pattern from the first magnetization signal and extracting a second harmonic pattern from the second magnetization signal; and
analyzing a difference between the first harmonic pattern and the second harmonic pattern to analyze a difference between the first measurement target material and the second measurement target material.

2. The material analysis method of claim 1, wherein each of the first and second measurement target materials comprises a super-paramagnetic material.

3. The material analysis method of claim 1, wherein the first and second measurement target materials comprise a same substance and have different sizes.

4. The material analysis method of claim 1, wherein each of the first and second measurement target materials has a size of about 0.1 nm to about 100 nm.

5. The material analysis method of claim 1, further comprising analyzing the difference between the first harmonic pattern and the second harmonic pattern to analyze a difference between a magnetic moment of the first measurement target material and a magnetic moment of the second measurement target material.

6. The material analysis method of claim 1, wherein each of the first magnetization signal and the second magnetization signal corresponds to a function defined based on a Langevin function.

7. The material analysis method of claim 6, wherein the extracting of the first harmonic pattern comprises extracting harmonic peaks by expanding the Langevin function of the first magnetization signal into a Taylor series, and
the extracting of the second harmonic pattern comprises extracting harmonic peaks by expanding the Langevin function of the second magnetization signal into a Taylor series.

8. The material analysis method of claim 6, wherein the Langevin function is expressed as
$$L ( x ) = coth ( x ) - \frac{1}{x} \\ x = \frac{{μ}_{0} {M}_{n} H ( t )}{{κ}_{h} T}$$
wherein a temperature (T) of the first measurement target material in the Langevin function of the first magnetization signal is equal to a temperature (T) of the second measurement target material in the Langevin function of the second magnetization signal.

9. The material analysis method of claim 1, further comprising adjusting a temperature of each of the first measurement target material and the second measurement target material by using a sample temperature adjustment device.

10. The material analysis method of claim 1, wherein the magnetic field is applied to each of the first measurement target material and the second measurement target material by a generation unit,
each of the first magnetization signal of the first measurement target material and the second magnetization signal of the second measurement target material is detected by a detection unit, and
each of the generation unit and the detection unit is provided in a space at room temperature and atmospheric pressure.

11. The material analysis method of claim 1, wherein the analyzing of the difference between the first harmonic pattern and the second harmonic pattern comprises fitting a first graph of the first magnetization signal according to a frequency based on the first harmonic pattern and fitting a second graph of the second magnetization signal according to a frequency based on the second harmonic pattern.

12. The material analysis method of claim 11, wherein, when a magnetic moment of the first measurement target material is different from a magnetic moment of the second measurement target material, the first graph has a different slope from the second graph at a same frequency.

13. A material analysis method comprising:
applying, by a generation unit, a magnetic field to each of a first material to be measured (hereinafter, referred to as a first measurement target material) and a second material to be measured (hereinafter, referred to as a second measurement target material);
detecting, by a detection unit, each of a first magnetization signal of the first measurement target material and a second magnetization signal of the second measurement target material;
extracting, by an analysis unit, a first harmonic pattern from the first magnetization signal and extracting, by the analysis unit, a second harmonic pattern from the second magnetization signal; and
analyzing, by the analysis unit, a difference between the first harmonic pattern and the second harmonic pattern to analyze a difference between the first measurement target material and the second measurement target material,
wherein, when detecting each of the first magnetization signal and the second magnetization signal, a temperature of each of the first and second measurement target materials is adjusted by a sample temperature adjustment device.

14. The material analysis method of claim 13, wherein each of the first magnetization signal and the second magnetization signal corresponds to a function defined based on a Langevin function, and
the Langevin function is expressed as
$$L ( x ) = coth ( x ) - \frac{1}{x} \\ x = \frac{{μ}_{0} {M}_{n} H ( t )}{{κ}_{h} T}$$
wherein the temperature (T) of the first measurement target material in the Langevin function of the first magnetization signal is equal to the temperature (T) of the second measurement target material in the Langevin function of the second magnetization signal.

15. A material analysis apparatus comprising:
a generation unit configured to apply a magnetic field to each of a first material to be measured (hereinafter, referred to as a first measurement target material) and a second material to be measured (hereinafter, referred to as a second measurement target material);
a detection unit configured to detect each of a first magnetization signal of the first measurement target material and a second magnetization signal of the second measurement target material;
an analysis unit configured to extract a first harmonic pattern from the first magnetization signal and extract a second harmonic pattern from the second magnetization signal; and
a sample temperature adjustment device configured to control each of a temperature of the first measurement target material and a temperature of the second measurement target material, inside the detection unit,
wherein the analysis unit analyzes a difference between the first harmonic pattern and the second harmonic pattern to analyze a difference between the first measurement target material and the second measurement target material.

16. The material analysis apparatus of claim 15, wherein each of the first magnetization signal and the second magnetization signal corresponds to a function defined based on a Langevin function, and
the Langevin function is expressed as
$$L ( x ) = coth ( x ) - \frac{1}{x} \\ x = \frac{{μ}_{0} {M}_{n} H ( t )}{{κ}_{h} T}$$
wherein the temperature (T) of the first measurement target material in the Langevin function of the first magnetization signal is equal to the temperature (T) of the second measurement target material in the Langevin function of the second magnetization signal.

17. The material analysis apparatus of claim 16, wherein the extracting of the first harmonic pattern comprises extracting harmonic peaks by expanding the Langevin function of the first magnetization signal into a Taylor series, and
the extracting of the second harmonic pattern comprises extracting harmonic peaks by expanding the Langevin function of the second magnetization signal into a Taylor series.

18. The material analysis apparatus of claim 15, wherein each of the first and second measurement target materials comprises a super-paramagnetic material.

19. The material analysis apparatus of claim 15, wherein the first and second measurement target materials comprise a same substance and have different sizes.

20. The material analysis apparatus of claim 15, wherein the analyzing of the difference between the first harmonic pattern and the second harmonic pattern comprises fitting a first graph of the first magnetization signal according to a frequency based on the first harmonic pattern and fitting a second graph of the second magnetization signal according to a frequency based on the second harmonic pattern, and
when a magnetic moment of the first measurement target material is different from a magnetic moment of the second measurement target material, the first graph has a different slope from the second graph at a same frequency.
